(19) United States
(12) Patent Application Publication
(10) Pub. No.: US 2026/0360911 A1
(43) Pub. Date: Nov. 12, 2026

(54) ASSEMBLY COMPRISING A WALL FEED-THROUGH SYSTEM

(71) Applicant: SAFRAN ELECTRICAL & POWER, Blagnac Cedex (FR)

(72) Inventors: Sébastien Thomassier, Moissy Cramayel (FR); Kevin Kappler, Moissy Cramayel (FR); Frédéric Pinard, Moissy Cramayel (FR)

(73) Assignee: SAFRAN ELECTRICAL & POWER, Blagnac Cedex (FR)

(21) Appl. No.: 19/125,726

(22) PCT Filed: Oct. 24, 2023
(86) PCT No.: PCT/FR2023/000163

§ 371 Date: Apr. 29, 2025

(30) Foreign Application Priority Data
Nov. 4, 2022 (FR) FR2211474

(51) Int. Cl. H01M 50/296; H05K 5/06

(52) U.S. Cl. CPC H01M 50/296; H05K 5/069; H01M 2220/20

(57) ABSTRACT

Assembly comprising a wall and a wall feed-through system configured to allow an electrical conductor to be fed through the wall and comprising an electrical conductor intended to be mounted in a first through-hole of the wall and comprising a shoulder and a threaded portion, on the opposite side to the shoulder.

The wall feed-through system comprises a sealing member configured to isolate the electrical conductor from the wall and configured to allow centring of the electrical conductor in the through-hole of the wall, a fastening member configured to fasten the electrical conductor and the sealing member to the wall, and an insulting member partially surrounding at least the electrical conductor and bearing axially between a second surface of the wall.

### TECHNICAL FIELD OF THE INVENTION

The present invention relates to the field of electrical energy accumulators such as batteries, in particular in the aeronautical field, likely to undergo a thermal runaway, known as thermal runaway with the acronym ‘TR’in English terms.

More particularly, the invention relates to electrical components known as ‘wall feed-through’ configured to pass one or more conductors through a wall while insulating the conductor from said wall.

### PRIOR ART

Electric energy accumulators comprise electrochemical elements or cells likely to undergo a thermal runaway that must be contained, in particular in the aeronautics field.

Electric energy accumulators or batteries are therefore made up of a containment zone capable of withstanding an event characteristic of thermal runaway, such as fire, high-temperature gas or even an explosion.

In order to provide electrical energy, the electrical energy accumulators are equipped with a power circuit configured to connect to the other electrical systems of an aircraft. The power circuit generally passes through the wall of said containment zone.

Using sealed wall feed-throughs or wall pass-throughs is known allowing the power circuit of an energy accumulator to pass through the wall of the containment zone, while limiting the thermal conduction between the electrical conductors and the connectors.

Sealed wall feed-throughs of the cable gland type made of plastics material and comprising a silicone seal or made of metal material are known.

Sealed wall feed-throughs made of metal material are also known, comprising a seal capable of withstanding high temperature and pressure or the sealed connectors in which the electrical conductor of the power circuit is sealed by ceramic material or glass.

However, during a thermal runaway of an energy accumulator element such as a battery, the temperature and pressure can increase significantly until they exceed 800 °C and 2 bar respectively, which generates stress on the wall feed-throughs.

This is because the internal heat of the battery is intended to be conveyed via the electrical power conductors, which can alter the mechanical properties of the connector or even compromise the sealing of the connector.

Existing wall feed-through solutions made of plastics material or comprising silicone seals cannot withstand high temperatures and pressures.

With regard to wall feed-throughs comprising a sealing material, these cannot be dismantled. In addition, the method for solidifying the sealing material requires a high-temperature furnace, which is difficult to apply to large parts that need to maintain their precise shape and dimensional tolerances. This is because the material tends to deform in furnaces at very high temperatures.

There is a need to optimise the wall feed-throughs so that they are resistant to high temperatures and pressures, i.e. above 800 °C and 2 bar, as well as high voltages and high currents, while maintaining a small dimensional footprint and easy to implement.

### DISCLOSURE OF THE INVENTION

The aim of the present invention is therefore to overcome the aforementioned disadvantages.

The objective of the invention is to improve the wall feed-throughs so that they are resistant to high temperatures and pressures, i.e. above 800 °C and 2 bar, as well as to high voltages and high currents, while retaining a small dimensional footprint and simple to implement.

Another object of the invention is to be able to disassemble the wall feed-through.

The object of the invention is an assembly comprising a wall and a wall feed-through or pass-through system configured to allow the passage of an electrical conductor through the wall and comprising an electrical conductor intended to be mounted in a first through hole in a wall.

The electrical conductor comprises a shoulder and a threaded part, on the side opposite to the shoulder.

Said wall feed-through system comprises:
a sealing member configured to isolate the electrical conductor from the wall and configured to allow centring of the electrical conductor in the through hole in the wall, said sealing member being mounted between the shoulder of the electrical conductor and a first surface of the wall,
a fastening member configured to fasten the electrical conductor and the sealing member to the wall, and
an insulating member partially surrounding at least the electrical conductor and in axial abutment between a second surface of the wall, opposite the first surface of the wall and the fastening member.

Thus the wall feed-through system is configured to allow the passage of said electrical conductor through a wall.

The sealing member prevents all contact between the electrical conductor and the wall.

Advantageously, the sealing member comprises at least one first bearing portion in axial abutment against the first surface of the wall.

In other words, said first support portion is sandwiched between the shoulder of the electric conductor and the wall.

Advantageously, the conductor comprises a body having an outside diameter smaller than the inside diameter of the hole passing through the wall and mounted in a bore of the sealing member.

Advantageously, the fastening member comprises in particular a body, for example cylindrical, provided with a tapping cooperating with a thread of a threaded area of the electrical conductor.

Thus the fastening member allows reversible fastening of the electrical conductor and the sealing member to the wall.

The electrical conductor may comprise, at at least one, or even each, of its free ends, a connection system configured to connect an additional electrical system, such as for example terminals, cables, busbars, or other types of connector.

Alternatively, the connection system could have a different shape, comprising, in a non-limiting manner, a flat and a through hole.

Advantageously, the electrical conductor is in the form of a metal bar.

Advantageously, the electrical conductor is made of conductive material, for example metallic material. The electrical conductor is preferably made of copper or aluminium.

Advantageously, at least the sealing member and the insulating member are made of non-conductive material, such as for example ceramic material, or of composite material or of another insulating material.

Thus the electrical conductor and the wall are electrically insulated from each other via the sealing member and the insulation member.

According to one embodiment, the sealing member comprises a second portion, for example cylindrical, with an outside diameter smaller than the outside diameter of the first portion and equal to the inside diameter of the through hole in the wall.

Thus the second portion is inserted into the through hole in the wall and ensures a satisfactory seal.

Alternatively, provision could be made for the sealing member not to comprise a second portion extending in the hole in the wall.

According to one embodiment, the second portion of the sealing member extends axially beyond the through hole in the wall. In other words, the axial dimension of the second portion is greater than the wall thickness.

According to one embodiment, the inside diameter of the hole in the insulating member is smaller than the inside diameter of the hole in the wall, for example in order to allow a radial clearance to remain between said insulation portion and the second portion of the sealing member.

According to one embodiment, the outside diameter of the body of the fastening member is greater than the inside diameter of the through hole in the wall.

For example, the outside diameter of the fastening member is smaller than the inside diameter of the through hole in the wall.

For example, the fastening member has an outside diameter smaller than the inside diameter of the hole in the insulating member, the fastening member comprising a shoulder bearing on the insulation portion.

According to one embodiment, the insulating member and the fastening member are made in the form of a single monolithic part.

In this embodiment, the entire fastening member may be made of non-conductive material.

For example, according to one variant, the insulating member has an outside diameter greater than the outside diameter of the body of the electrical conductor and comprises a hole with an inside diameter smaller than the outside diameter of said body.

According to one embodiment, the axial dimension of the second portion of the sealing member is less than the wall thickness and the inside diameter of the insulation portion is equal to the outside diameter of the electrical conductor.

In the case where the axial dimension of the second portion of the sealing member is less than the thickness of the wall, provision could be made for the inside diameter of the insulation portion to be equal to the outside diameter of the electrical conductor.

According to one embodiment, in the case where the insulating member is separate from the fastening member, the fastening member is made of conductive material, for example of metallic material, such as stainless steel, steel, or titanium, or other metallic material.

According to one embodiment, the outside diameter of the fastening member is smaller than the inside diameter of the through hole in the wall.

Alternatively, the body of the fastening member has an outside diameter greater than the inside diameter of the hole in the insulation portion and the fastening member comprises a cylindrical interface with an outside diameter greater than the inside diameter of the hole in the insulation portion in axial support on the insulation portion.

According to a variant embodiment, the body of the fastening member has an outside diameter smaller than the inside diameter of the hole in the insulation portion, the fastening member comprising a shoulder with an outside diameter larger than the inside diameter of the hole in the insulation portion bearing on the insulation portion.

According to another aspect, the invention relates to a vehicle comprising at least one energy accumulator comprising a containment zone delimited by a containment zone wall and a wall feed-through system of the assembly as described previously.

### BRIEF DESCRIPTION OF THE DRAWINGS

Further aims, features and advantages of the invention will become apparent from reading the following description, provided solely by way of non-limiting example, with reference to the accompanying drawings in which:

FIG. 1 is a perspective view of a wall feed-through system mounted on a wall according to a first embodiment;

FIG. 2 is an exploded perspective view of the wall feed-through system of FIG. 1;

FIG. 3 is a cross-sectional view of the wall feed-through system of FIG. 1;

FIG. 4 is a sectional view of a wall feed-through system mounted on a wall according to a second embodiment;

FIG. 5 is a cross-sectional view of a wall feed-through system mounted on a wall according to a third embodiment;

FIG. 6 is a cross-sectional view of a wall-mounted wall feed-through system according to a fourth embodiment; and

FIG. 7 is a cross-sectional view of a wall feed-through system mounted on a wall according to a fifth embodiment.

### DETAILED DISCLOSURE OF AT LEAST ONE EMBODIMENT

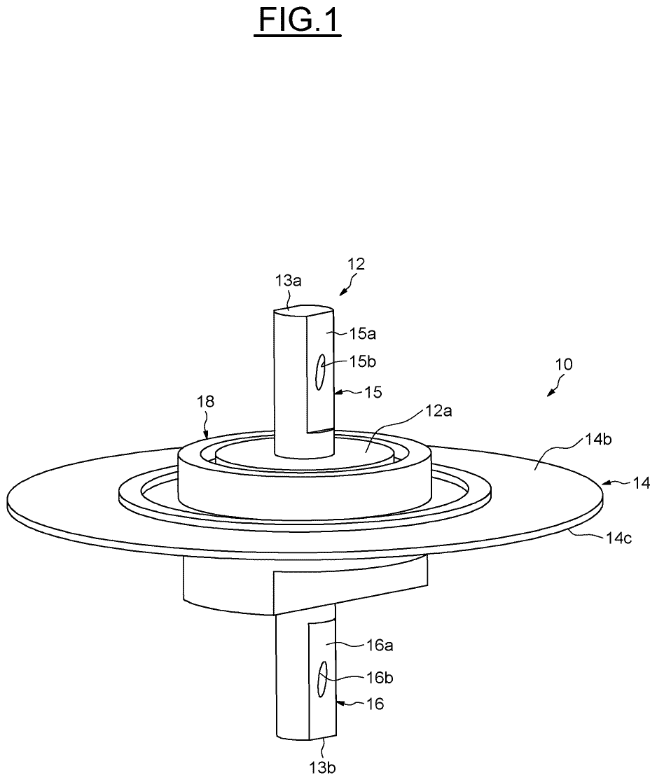

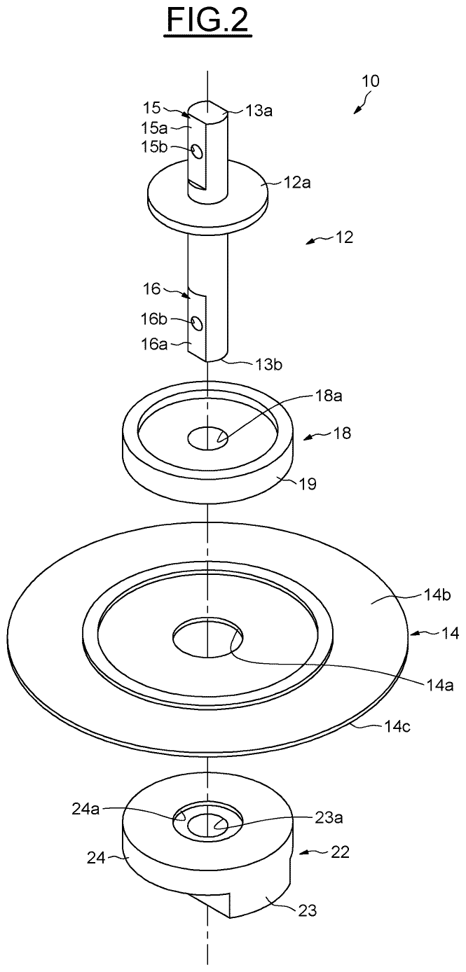

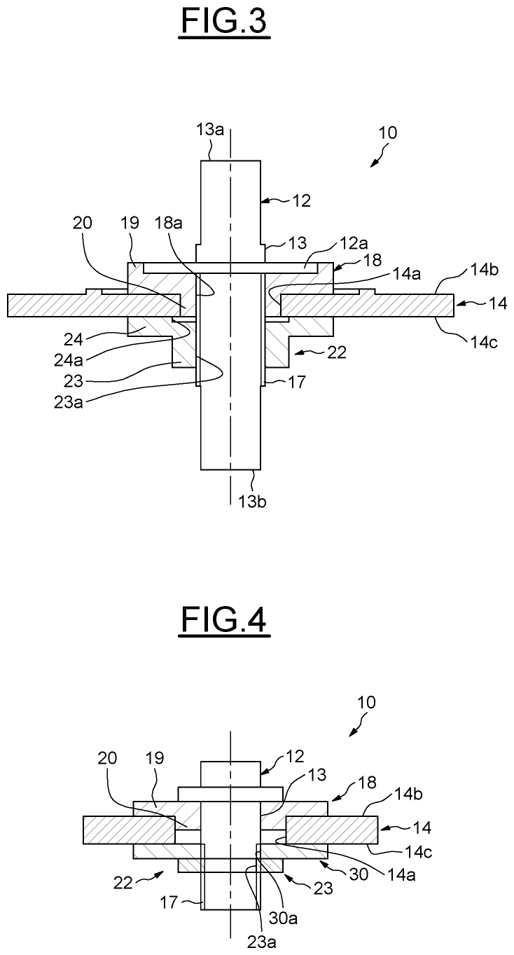

With reference to the example illustrated in FIGS. 1 to 3, a wall feed-through or wall pass-through system 10 is configured to allow the passage of an electrical conductor 12 through a wall 14.

The wall 14 is, for example, the wall of a containment area of an electrical energy accumulator or battery capable of withstanding an event characteristic of a thermal runaway, such as fire, high-temperature gas, or even an explosion.

The wall 14 comprises a through hole 14a into which the electrical conductor 12 of the wall through system 10 is inserted.

The electrical conductor 12 here has the form of a metal bar called ‘busbar’ in English terms.

As illustrated, the electrical conductor 12 comprises a cylindrical body 13 comprising at each of its free ends 13a, 13b, a connection system 15, 16, comprising, in a non-limiting manner, a flat 15a, 16a and a through hole 15b, 16b.

The connection system 15, 16 is configured to connect an additional electrical system (not shown), such as for example terminals, cables, busbars, or other types of connector. In a variant, the connection system may have a different form.

The electrical conductor 12 further comprises a shoulder 12a and a threaded part 17, on the side opposite the shoulder 12a.

The outside diameter of the body 13 of the electrical conductor 12 is smaller than the inside diameter of the through hole 14a in the wall 14.

The wall feed-through system 10 furthermore comprises a sealing member 18 configured to insulate the electrical conductor 12 from the wall 14.

As illustrated in the figures, the sealing member 18 comprises a bore 18a into which the body 13 of the electrical conductor 12 is inserted. The sealing member 18 is configured to allow centring of the electrical conductor 12 in the through hole 14a in the wall 14 while avoiding any contact between said electrical conductor 12 and the wall 14.

The sealing member 18 comprises a first support portion 19 in axial abutment against a first surface 14b of the wall 14. Said first support portion 19 is sandwiched between the shoulder 12a of the electrical conductor 12 and the wall 14.

In the example illustrated in FIGS. 1 to 3, the sealing member 18 comprises a second portion 20, cylindrical, with an outside diameter smaller than the outside diameter of the first portion 19 and equal to the inside diameter of the through hole 14a in the wall 14.

Thus the second portion 20 is inserted into the through hole 14a in the wall 14 and makes it possible to guarantee a satisfactory seal.

The second portion 20 extends, here, axially beyond the through hole in the wall 14. In other words, the axial dimension of the second portion 20 is greater than the thickness of the wall 14.

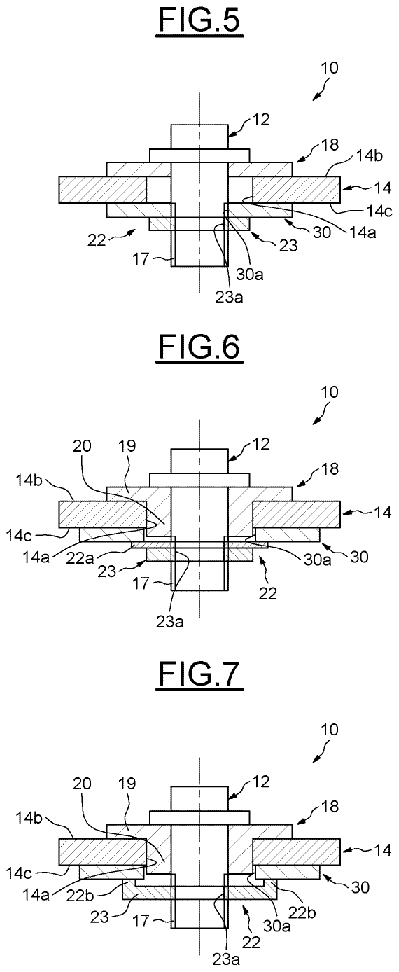

In a variant, as can be seen in FIGS. 4 and 5, the second portion 20 of the sealing member does not extend axially beyond the through hole in the wall 14. In other words, the axial dimension of the second portion 20 is less than the thickness of the wall 14.

The wall feed-through system 10 furthermore comprises a fastening member 22 configured to fix the electrical conductor 12 and the sealing member 18 to the wall 14.

As illustrated in the figures, the fastening member 22 comprises a body 23, here cylindrical, provided with a tapped hole 23a cooperating with the thread of the threaded area 17 of the electrical conductor 12. Thus the fastening member 22 allows reversible fastening of the electrical conductor 12 and the sealing member 18 to the wall 14.

In the example illustrated in FIGS. 1 to 3, the outside diameter of the body 23 of the fastening member 22 is greater than the inside diameter of the through hole 14a of the wall 14.

In a variant, provision could be made for the outside diameter of the body 23 of the fastening member 22 to be smaller than the inside diameter of the through hole 14a of the wall 14, as can be seen in FIGS. 4 to 6.

In the example illustrated in FIGS. 1 to 3, the fastening member 22 comprises an insulation portion 24 with an outside diameter greater than the outside diameter of the body 23 and comprising a hole 24a with an inside diameter smaller than the outside diameter of the body 23.

The insulation portion 24 is in axial abutment against a second surface 14c of the wall 14, opposite the first surface 14b.

The inside diameter of the hole 24a in the insulation portion 24 is smaller than the inside diameter of the hole 14a of the wall 14 in order to allow a radial clearance to remain between said insulation portion 24 and the second portion 20 of the sealing member 18.

In a variant, in the case where the axial dimension of the second portion 20 of the sealing member 18 is less than the thickness of the wall 14, provision could be made for the inside diameter of the insulation portion 24 to be equal to the outside diameter of the electrical conductor 12, as can be seen in FIGS. 4 and 5.

The electrical conductor 12 and the wall 14 are made of conductive material, for example metallic material.

The electrical conductor 12 is preferably made of copper or aluminium.

The wall is for example made of stainless steel, steel, or titanium, or other metallic material.

The sealing member 18 and the fastening member 22 are made of non-conductive material, such as for example ceramic material, or composite material or another insulating material.

The electrical conductor 12 and the wall 14 are electrically insulated from each other by means of the sealing member 18 and the fastening member 22.

FIG. 4 illustrates another embodiment, in which the same elements bear the same references and which differs from the embodiment illustrated in FIGS. 1 to 3 only in that the axial dimension of the second portion 20 of the sealing member 18 is less than the thickness of the wall 14, and that the insulation portion 30 is a part separate from the fastening member 22. The inside diameter of the insulation portion 30 is equal to the outside diameter of the electrical conductor 12.

As illustrated in FIG. 4, the insulation portion 30 is an additional insulating member 30, in the form of an insulating washer, mounted between the body 23 of the fastening member 22 and the second surface 14c of the wall 14.

The insulation portion 30 is made of non-conductive material, such as for example ceramic material, or composite material or other insulating material.

FIG. 5 illustrates another embodiment, in which the same elements bear the same references and which differs from the embodiment illustrated in FIG. 4 only in that the sealing member 18 does not comprise a second portion extending in the hole 14a in the wall 14.

FIG. 6 illustrates another embodiment, wherein the same elements bear the same references and which differs from the embodiment illustrated in FIGS. 1 to 3 only in that the insulation portion 30 is a part separate from the fastening member 22. The inside diameter of the insulation portion 30 is greater than the inside diameter of the hole 14a in the wall 14.

As illustrated in FIG. 6, the insulation portion 30 is an additional insulating member 30, in the form of an insulating washer, mounted between the body 23 of the fastening member 22 and the second surface 14c of the wall 14.

The insulation portion 30 is made of non-conductive material, such as for example ceramic material, or composite material or other insulating material.

As illustrated in FIG. 6, the body 23 of the fastening member 22 has an outside diameter smaller than the inside diameter of the hole 30a in the insulation portion 30. The fastening member 22 comprises a shoulder 22a with an outside diameter greater than the inside diameter of the hole 30a in the insulation portion 30 in abutment on the insulation portion 30.

FIG. 7 illustrates another embodiment, wherein the same elements bear the same references and which differs from the embodiment illustrated in FIG. 6 only in that the body 23 of the fastening member 22 has an outside diameter greater than the inside diameter of the hole 30a in the insulation portion 30 and that the fastening member 22 comprises a cylindrical interface 22b with an outside diameter greater than the inside diameter of the hole 30a in the insulation portion 30 in axial support on the insulation portion 30.

In the example illustrated in FIGS. 4 to 7, the fastening member 22 is made of conductive material, for example of metallic material, such as for example of stainless steel, steel, or titanium, or other metallic material.

The portion or second insulating member 30 makes it possible to insulate the fastening member 22 from the wall 14.

Thanks to the invention, the wall feed-through system is detachably attached to a wall, while allowing the electrical connector to be isolated from said wall. The wall feed-through system is configured to withstand high temperatures and pressures, i.e. above 800 °C and 2 bar, as well as high voltages and high currents, while maintaining a small dimensional footprint and easy to implement.

1. Assembly comprising a wall and a wall feed-through system configured to allow passage of an electrical conductor through the wall and comprising an electrical conductor intended to be mounted in a first through hole of the wall, the electrical conductor comprising a shoulder and a threaded part, on the side opposite the shoulder, and said wall feed-through system further comprising:
a sealing member configured to isolate the electrical conductor from the wall and configured to allow centring of the electrical conductor in the first through hole of the wall, said sealing member being mounted between the shoulder of the electrical conductor and a first surface of the wall, said sealing member comprising at least one first support portion in axial abutment against the first surface of the wall and a second portion with an outside diameter smaller than an outside diameter of the first portion and equal to an inside diameter of the first through hole of the wall;
a fastening member configured to fasten the electrical conductor and the sealing member to the wall; and
an insulating member partially surrounding at least the electrical conductor and in axial abutment between a second surface of the wall, opposite to the first surface of the wall and the fastening member, wherein the second portion of the sealing member extends axially beyond the through hole of the wall.

2. (canceled)

3. Assembly according to claim 1, wherein the conductor comprises a body having an outside diameter smaller than the inside diameter of the first through hole of the wall and mounted in a bore of the sealing member.

4. Assembly according to claim 1, wherein the fastening member comprises a tapping cooperating with a thread of a threaded area of the electrical conductor.

5. Assembly according to claim 1, wherein the electrical conductor comprises, at at least one of its free ends, a connection system configured to connect an additional electrical system.

6. Assembly according to claim 1, wherein the electrical conductor is in the form of a metal bar.

7. Assembly according to claim 1, wherein the electrical conductor is made of conductive material.

8. Assembly according to claim 1, wherein at least the sealing member and the insulating member are made of non-conductive material.

9.-11. (canceled)

12. Assembly according to claim 1, wherein the outside diameter of a body of the fastening member is greater than the inside diameter of the first through hole of the wall.

13. Assembly according to claim 1, wherein the outside diameter of the fastening member is less than the inside diameter of the first through hole of the wall.

14. Assembly according to claim 13, wherein the fastening member has an outside diameter smaller than the inside diameter of a hole of the insulating member, the fastening member comprising a shoulder in abutment on the insulation member.

15. Assembly according to claim 1, wherein the insulating member and the fastening member are made in the form of a single monolithic part.

16. (canceled)

17. Assembly according to claim 1, wherein the fastening member is made of conductive material.

18. Vehicle comprising at least one energy accumulator comprising a containment zone delimited by a containment-zone wall and a wall feed-through system of the assembly of claim 1.
